(19) United States
(12) Patent Application Publication
(10) Pub. No.: US 2005/0047086 A1
(43) Pub. Date: Mar. 3, 2005

(54) Heat dissipation apparatus and method

(76) Inventors: Elias Gedamu, Calgary (CA); Denise Man, Ft. Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/649,057

(22) Filed: Aug. 27, 2003

(51) Int. Cl. H05K 7/20

(52) U.S. Cl. 361/695

(57) ABSTRACT

Disclosed are a heat dissipation computer and method. In one embodiment, a heat dissipation apparatus comprises a heat sink that is adapted to receive a processor, the heat sink forming part of an enclosed interior passage, and at least one prong extending from the heat sink and positioned within the interior passage, wherein the enclosed interior passage is adapted to receive fluid forced through the interior passage. In one embodiment, a method for dissipating heat generated by a processor comprises forming an interior passage in part with a heat sink to which the processor is mounted, and forcing the fluid through the interior passage and over prongs contained within the interior passage and extending from the heat sink.

### BACKGROUND

Computers comprise one or more processors, such as microprocessors, that generate heat during use. To avoid overheating a processor, which can cause computer failure, processors are often mounted to heat sinks that draw heat away from the processor. Normally, such heat sinks are cooled via forced convection through the use of one or more fans provided within the computer “box.” The airflow created by such fans transfers heat from the processor to the ambient air.

A typical heat sink comprises a relatively thin plate of metal to which the processor is mounted. The dimensions of the heat sink depend upon the particular configuration and operation of the processor. By way of example, the heat sink may comprise length and width dimensions of about 6 inches by 3 inches. Although such dimensions are not particularly large in an absolute sense, the dimensions can be a significant factor in terms of computer design, especially when the computer being designed comprises multiple processors. For instance, a server computer may include ten or more such processors, each of which requiring its own heat sink to dissipate heat. In such a case, it may be difficult to fit all of the processors, and their associated heat sinks, within the computer box. Furthermore, the aggregate weight of the heat sinks may increase the weight of the computer as well as the cost of shipping the processors.

Although it would be desirable to decrease the size of the processor heat sinks to avoid the above-described problems, simple size reduction can result in inadequate heat dissipation and, therefore, computer failure. Accordingly, needed is a heat dissipation apparatus and method with which adequate heat transfer can be obtained with more compact and/or lighter apparatus.

### SUMMARY

Disclosed are a heat dissipation apparatus and method. In one embodiment, a heat dissipation apparatus comprises a heat sink that is adapted to receive a processor, the heat sink forming part of an enclosed interior passage, and at least one prong extending from the heat sink and positioned within the interior passage, wherein the enclosed interior passage is adapted to receive fluid forced through the interior passage.

In one embodiment, a method for dissipating heat generated by a processor comprises forming an interior passage in part with a heat sink to which the processor is mounted, and forcing the fluid through the interior passage and over prongs contained within the interior passage and extending from the heat sink.

### BRIEF DESCRIPTION OF THE DRAWINGS

The disclosed apparatus and method can be better understood with reference to the following drawings. The components in the drawings are not necessarily to scale.

FIG. 1 is a partial cut-away perspective view of an example embodiment of a heat dissipation apparatus.

FIG. 2 is a side view of the heat dissipation apparatus of FIG. 1.

FIG. 3 is a top view of the heat dissipation apparatus of FIG. 1, with a top wall of the apparatus being removed.

FIG. 4 is a bottom view of the heat dissipation apparatus of FIG. 1.

FIG. 5 is a schematic cross-sectional view of the heat dissipation apparatus of FIG. 1 taken along line 5-5 in FIG. 3 and illustrates fluid flow through the heat dissipation apparatus within a computer.

FIG. 6 is a flow diagram of an embodiment of a method for dissipating heat generated by a processor.

### DETAILED DESCRIPTION

As described above, the size and/or weight of conventional heat sinks used in conjunction with computer processors can be undesirable, particularly in cases in which multiple processors are to be provided in a single computer box. As is described in the following, however, adequate heat dissipation can be achieved with smaller and/or lighter heat dissipation apparatus through use of a heat dissipation apparatus that includes an enclosed passage containing prongs that extend from a heat sink to which the processor is mounted. Fluid, such as air, can be forced into an inlet end of the heat dissipation apparatus and can be drawn out of the heat dissipation apparatus at an outlet end so that heat transmitted to the heat sink and the prongs may be removed, thereby cooling the processor.

Disclosed herein is a heat dissipation apparatus that enables such cooling and a method for dissipating heat generated by a processor. Although specific embodiments are shown in the figures and are described herein, these embodiments are provided for purposes of example only to describe the apparatus and method.

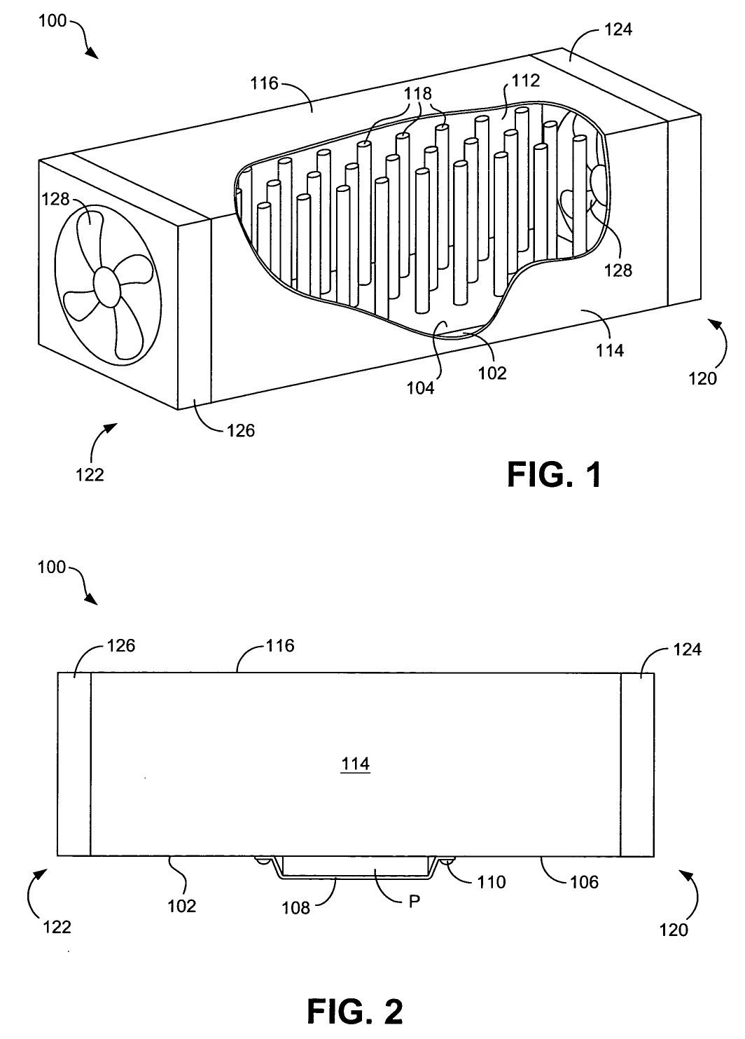

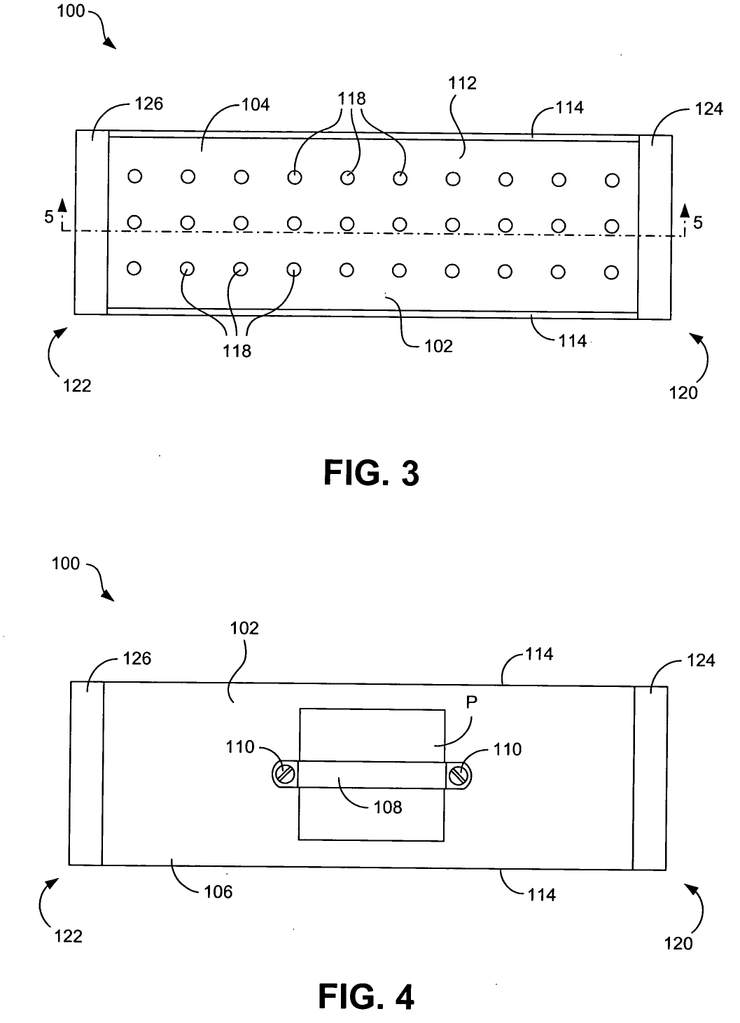

Referring now in more detail to the drawings, in which like numerals indicate corresponding parts throughout the several views, FIGS. 1-4 illustrate a heat dissipating apparatus 100 that can be used to dissipate heat generated by a processor P, such as a microprocessor. As indicated best in the partial cut-away view of FIG. 1, the heat dissipation apparatus 100 includes a heat sink 102, which may comprise a relatively thin plate. The heat sink 102 is constructed of a thermally-conductive material, such as a metal (e.g., aluminum). The size and dimensions of the heat sink 102 may be selected to suit the particular application in which the heat dissipation apparatus 100 is to be used. By way of example, however, the heat sink 102 may have length and width dimensions of approximately 3 inches by 1.5 inches and, therefore, may be significantly smaller than known processor heat sinks.

The heat sink 102 comprises a top surface 104 and a bottom surface 106 (best shown in FIG. 4). Mounted to the bottom surface 106 of the heat sink 102 is a processor P. The processor P may be removably mounted to the heat sink 102 such that the processor or its heat dissipation apparatus 100 may be replaced, if desired. For example, the processor P can be mounted to the heat sink bottom surface 106 with a mounting bracket 108 that is secured to the heat sink 102 with one or more fasteners 110, such as screws.

As is shown best in the cut-away view of FIG. 1, the apparatus 100 also includes enclosure walls that enclose an interior passage 112 of the apparatus. By way of example, the enclosure walls include opposed side walls 114 and a top wall 116 that is positioned opposite the heat sink 102. These walls may comprise separate plates of a thermally-conductive material (e.g., metal) that are connected to the heat sink 102 and each other to form the interior passage 112. Alternatively, however, one or more of the walls may be unitarily-formed with the heat sink 102. In such a case, the wall(s) and the heat sink 102 may be formed together from a single piece of material.

Contained within the interior passage 112 are prongs 118 that extend up from the heat sink 102. As indicated in FIG. 1, the prongs 118 may be configured as cylindrical rods. The size and number of the prongs 114 may be selected to suit the particular application in which the heat dissipation apparatus 100 is used. By way of example, however, the prongs 118 may be about 1-2 inches tall and may number from about 10-50 (30 prongs are shown in the embodiment of FIGS. 1-4). The prongs 118 are also constructed of a thermally-conductive material, such as a metal. By way of example, the prongs 118 may be unitarily-formed with the heat sink 102. In such a case, the heat sink 102 and the prongs 118 may be manufactured (e.g., machined) from a single piece of material. Alternatively, however, the prongs 118 may be separately manufactured and then mounted to the heat sink 102, for instance by soldering, press-fitting, or gluing.

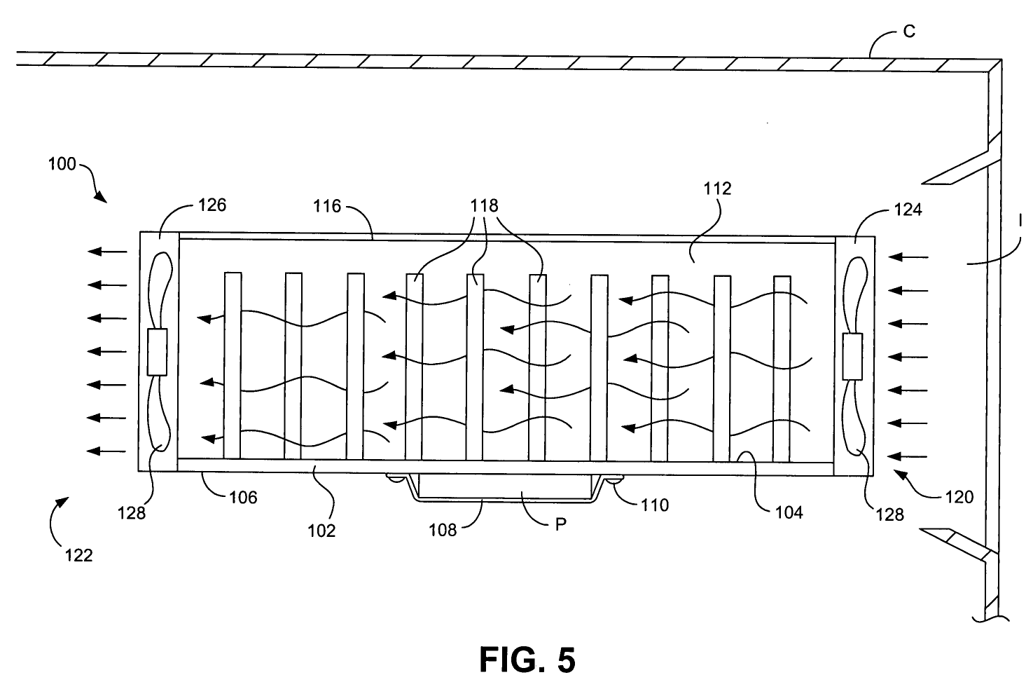

The heat dissipation apparatus 100 further comprises an inlet end 120 and an outlet end 122. Positioned at each of these ends 120, 122 is a fan module. Specifically, positioned at the inlet end 120 is an inlet fan module 124, and positioned at the outlet end 122 is an outlet fan module 126. Each of the fan modules 124, 126 includes one or more fans 128 that is used to force fluid (e.g., air) through the heat dissipation apparatus 100. More particularly, the inlet fan module 124 is used to force fluid into the interior passage 112, and the outlet fan module 126 is used to draw fluid out of the interior passage such that the fluid rapidly flows through the interior passage so as to remove heat transmitted to the heat sink 102 and the prongs 118 (see FIG. 5).

Operation of the heat dissipation apparatus 100 will now be discussed in reference to FIG. 5. When a computer C, for example a server, in which the heat dissipation apparatus 100 is used is powered, at some time during use of the computer the processor P is activated to perform various processing, and the fan modules 124, 126 are activated to spin their respective fans 128. The fans 128 can be operated continuously, or intermittently during computer and/or processor use as necessary. As the fans 128 spin, fluid, such as ambient air from outside of the computer C, is drawn into the fan of the inlet fan module 124 (at the right end of the apparatus 100 in FIG. 5) through an inlet I of the computer, and is forced into the interior passage 112. Once in the interior passage 112, the fluid flows past and between the prongs 118 so as to remove heat from the prongs. In addition, the fluid flows past the heat sink 102 and the various walls that define the interior passage 112 to likewise remove heat from those components.

As the fluid travels within the interior passage 112, the fluid is drawn toward the outlet (or exit) end 122 of the apparatus 100 (at the left end of the apparatus in FIG. 5) by the fan 128 of the outlet fan module 126. Accordingly, the fluid ultimately is expelled from the interior passage 112 at the outlet end 122 of the apparatus 100, for instance into the air outside of the computer box.

In each of the above-described embodiments, air may be drawn directly from the ambient air outside of the computer in which the heat dissipation device is provided so as to provide relatively cool air to the heat dissipating apparatus for the purpose of transferring heat. Alternatively, however, air (or other fluid) may be drawn from within the computer interior, if desired. In similar manner, air exhausted from a heat dissipation apparatus can be directly exhausted to the ambient air outside of the computer so as to remove heat from the computer interior. Alternatively, however, the air (or other fluid) may simply be exhausted to the computer interior and then removed from the computer with a separate apparatus (e.g., a separate computer exhaust fan).

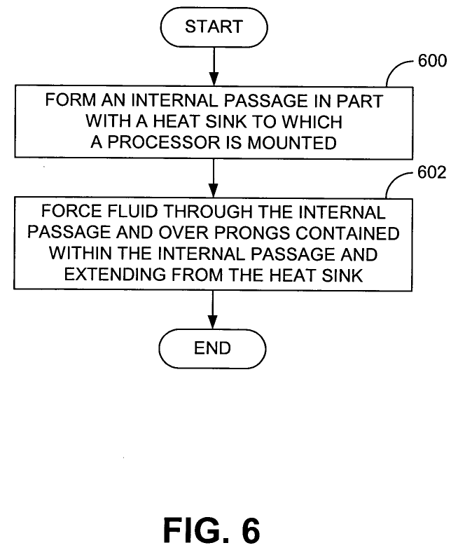

In view of the above, an embodiment of a method for dissipating heat from a processor can be summarized as indicated in the flow diagram of FIG. 6. Beginning with block 600 of that figure, an interior passage is formed in part with a heat sink to which the processor is mounted. Once formed, fluid is forced through the interior passage and over prongs contained within the interior passage and extending from the heat sink, as indicated in block 602.

1. A heat dissipation apparatus, comprising:
a heat sink that is adapted to receive a processor, the heat sink forming part of an enclosed interior passage; and
at least one prong extending from the heat sink and positioned within the interior passage;
wherein the enclosed interior passage is adapted to receive fluid forced through the interior passage.

2. The apparatus of claim 1, wherein the heat sink comprises a relatively thin plate.

3. The apparatus of claim 1, wherein the heat sink has a top surface and a bottom surface, wherein the at least one prong extends from the top surface and wherein the bottom surface is adapted to receive a processor removably mounted thereto.

4. The apparatus of claim 1, wherein the at least one prong comprises a cylindrical rod.

5. The apparatus of claim 1, further comprising walls that enclose the interior passage, at least one of the walls being connected to the heat sink.

6. The apparatus of claim 5, wherein the walls include opposed side walls that are connected to the heat sink and a top wall that is positioned opposite the heat sink.

7. The apparatus of claim 1, wherein the apparatus has an inlet end that is adapted to receive a forced fluid flow and an outlet end that is adapted to exhaust the fluid flow.

8. The apparatus of claim 7, further comprising an inlet fan module positioned at the inlet end of the apparatus, the inlet fan module being adapted to force fluid into the interior passage.

9. The apparatus of claim 7, further comprising an outlet fan module positioned at the outlet end of the apparatus, the outlet fan module being adapted to draw fluid out of the interior passage.

10. A heat dissipation apparatus, comprising:
a heat sink having a top surface and a bottom surface, the bottom surface being adapted to receive a processor that is removably mounted thereto;
enclosure walls that together with the heat sink form an enclosed interior passage;
prongs contained within the enclosed interior passage, the prongs extending from the top surface of the heat sink; and
a fan positioned at one of an inlet end and an outlet end of the apparatus, the fan facilitating flow of fluid through the enclosed interior passage and over the prongs.

11. The apparatus of claim 10, wherein the heat sink comprises a relatively thin plate.

12. The apparatus of claim 10, wherein the heat sink and the enclosure walls are made of a thermally-conductive material.

13. The apparatus of claim 12, wherein the heat sink and the enclosure walls are made of a metal material.

14. The apparatus of claim 10, wherein the prongs comprise cylindrical rods.

15. The apparatus of claim 14, wherein the cylindrical rods are made of a metal material.

16. The apparatus of claim 12, wherein the apparatus has an inlet end that is adapted to receive a forced fluid flow and an outlet end that is adapted to exhaust the fluid flow.

17. The apparatus of claim 16, further comprising an inlet fan module positioned at the inlet end of the apparatus, the inlet fan module being adapted to force fluid into the interior passage.

18. The apparatus of claim 16, further comprising an outlet fan module positioned at the outlet end of the apparatus, the outlet fan module being adapted to draw fluid out of the interior passage.

19-24. Canceled.

25. A method for dissipating heat generated by a processor, the method comprising:
forming an interior passage in part with a heat sink to which the processor is mounted; and
forcing the fluid through the interior passage and over prongs contained within the interior passage and extending from the heat sink.

26. The method of claim 25, wherein forming an interior passage comprises forming an interior passage with the heat sink and enclosure walls.

27. The method of claim 25, wherein forcing fluid through the interior passage comprises forcing fluid into the interior passage using a fan positioned at an inlet end of a heat dissipation apparatus.

28. The method of claim 27, wherein forcing fluid through the interior passage comprises drawing fluid out of the interior passage using a fan positioned at an outlet end of a heat dissipation apparatus.

29. A computer, comprising:
a processor; and
a heat dissipation apparatus that includes a heat sink that is adapted to receive the processor and that forms part of an enclosed interior passage, the heat dissipation apparatus further including at least one prong extending from the heat sink and positioned within the interior passage, wherein the enclosed interior passage is adapted to receive fluid forced through the interior passage.

30. The computer of claim 29, wherein the heat sink comprises a relatively thin plate.

31. The computer of claim 29, wherein the heat sink has a top surface and a bottom surface and the at least one prong extends from the top surface and wherein the bottom surface is adapted to receive a processor removably mounted thereto.

32. The computer of claim 29, wherein the at least one prong comprises a cylindrical rod.

33. The computer of claim 29, wherein the heat dissipation apparatus further comprises walls that enclose the interior passage, at least one of the walls being connected to the heat sink.

34. The computer of claim 33, wherein the walls include opposed side walls that are connected to the heat sink and a top wall that is positioned opposite the heat sink.

35. The computer of claim 29, wherein the heat dissipation apparatus further includes an inlet end that is adapted to receive a forced fluid flow and an outlet end that is adapted to exhaust the fluid flow.

36. The computer of claim 35, wherein the heat dissipation apparatus further includes an inlet fan module positioned at the inlet end of the computer, the inlet fan module being adapted to force fluid into the interior passage.

37. The computer of claim 35, wherein the heat dissipation apparatus further includes an outlet fan module positioned at the outlet end of the computer, the outlet fan module being adapted to draw fluid out of the interior passage.
